(19) United States
(12) Patent Application Publication
(10) Pub. No.: US 2009/0206465 A1
(43) Pub. Date: Aug. 20, 2009

(54) SEMICONDUCTOR CHIP PACKAGE STRUCTURE FOR ACHIEVING ELECTRICAL CONNECTION WITHOUT USING A WIRE-BONDING PROCESS AND METHOD FOR MAKING THE SAME

(75) Inventors: BILY WANG, HSINCHU CITY (TW); HUNG-CHOU YANG, HSINCHU COUNTY 302 (TW); JENG-RU CHANG, HSINCHU COUNTY 303 (TW)

Correspondence Address: ROSENBERG, KLEIN & LEE, 3458 ELLICOTT CENTER DRIVE-SUITE 101, ELLICOTT CITY, MD, 21043, US

(73) Assignee: HARVATEK CORPORATION, HSINCHU CITY (TW)

(21) Appl. No.: 12/243,180

(22) Filed: Oct. 1, 2008

(30) Foreign Application Priority Data
Feb. 20, 2008 (TW) 97105953

(51) Int. Cl. H01L 23/48; H01L 21/50

(52) U.S. Cl. 257/690; 438/113; 257/E23.01; 257/E21.499

(57) ABSTRACT

A semiconductor chip package structure for achieving electrical connection without using a wire-bonding process includes: a package unit, a semiconductor chip, a first insulative layer, first conductive layers, a second insulative layer, and second conductive layers. The package unit has a receiving groove. The semiconductor chip receives in the receiving groove and has a plurality of conductive pads disposed on its top surface. The first insulative layer is formed among the conductive pads in order to insulate the conductive pads from each other. The first conductive layers are formed on the first insulative layer, and one side of each first conductive layer is electrically connected to the corresponding conductive pad. The second insulative layer is formed among the first conductive layers in order to insulate the first conductive layers from each other. The second conductive layers are respectively formed on the other opposite sides of the first conductive layers.

### BACKGROUND OF THE INVENTION

1. Field of the Invention

The present invention relates to a semiconductor chip package structure and a method for making the same, and particularly relates to a semiconductor chip package structure for achieving electrical connection without using a wire-bonding process and a method for making the same.

2. Description of Related Art

Referring to FIG. 1, a known LED package structure that is packaged via a wire-bonding process. The known LED package structure includes a substrate 1a, an LED (light emitting diode) 2a disposed on the substrate, two wires 3a, and a fluorescence colloid 4a.

The LED 2a has a light-emitting surface 20a opposite to the substrate 1a. The LED 2a has a positive pole area 21a and a negative pole area 22a electrically connected to two corresponding positive and negative pole areas 11a, 12a of the substrate 1a via the two wires 3a respectively. Moreover, the fluorescence colloid 4a is covered on the LED 2a and the two wires 3a for protecting the LED 2a.

However, the method of the prior art not only increases manufacture time and cost, but also leads to uncertainty about the occurrence of bad electrical connections in the LED package structure of the prior art resulting from the wire-bonding process. Moreover, the two sides of the two wires 3a are respectively disposed on the positive and negative pole areas 21a, 22a. Hence, when the light source of the LED 2a is projected outwardly from the light-emitting surface 20a and through the fluorescence colloid 4a, the two wires 3a will produce two shadow lines within the light emitted by the LED 2a and thus affect the LED's light-emitting efficiency.

### SUMMARY OF THE INVENTION

One particular aspect of the present invention is to provide a semiconductor chip package structure for achieving electrical connection without using a wire-bonding process and a method for making the same. Because the semiconductor chip package structure of the present invention can achieve electrical connection without using a wire-bonding process, the present invention can omit the wire-bonding process and avoid bad electrical connection in the semiconductor chip package structure.

In order to achieve the above-mentioned aspects, the present invention provides a semiconductor chip package structure for achieving electrical connection without using a wire-bonding process, including: a package unit, at least one semiconductor chip, a first insulative unit, a first conductive unit, a second insulative unit, and a second conductive unit.

The package unit has at least one receiving groove. The at least one semiconductor chip is received in the at least one receiving groove and has a plurality of conductive pads disposed on its top surface. The first insulative unit has at least one first insulative layer formed among the conductive pads in order to insulate the conductive pads from each other. The first conductive unit has a plurality of first conductive layers formed on the at least one first insulative layer, and one side of each first conductive layer is electrically connected to the corresponding conductive pad. The second insulative unit has at least one second insulative layer formed among the first conductive layers in order to insulate the first conductive layers from each other. The second conductive unit has a plurality of second conductive layers respectively formed on the other opposite sides of the first conductive layers.

In order to achieve the above-mentioned aspects, the present invention provides a method of making semiconductor chip package structures for achieving electrical connection without using a wire-bonding process, including: arranging at least two semiconductor chips on an adhesive polymeric material, wherein each semiconductor chip has a plurality of conductive pads disposed on its top surface and the conductive pads face the adhesive polymeric material; covering a package unit on the at least two semiconductor chips; and overturning the package unit and removing the adhesive polymeric material in order to make the conductive pads exposed faceup.

The method further includes: forming at least one first insulative layer among the conductive pads in order to insulate the conductive pads from each other; forming a plurality of first conductive layers on the at least one first insulative layer for respectively and electrically connecting to the conductive pads; forming a plurality of second insulative layers among the first conductive layers in order to insulate the first conductive layers from each other; respectively forming a plurality of second conductive layers on the first conductive layers for electrically connecting to the conductive pads; and forming at least two semiconductor chip package structures by a cutting process.

In order to achieve the above-mentioned aspects, the present invention provides a method of making semiconductor chip package structures for achieving electrical connection without using a wire-bonding process, including: forming at least one first insulative material on an adhesive polymeric material; arranging at least two semiconductor chips on the at least one first insulative material, wherein each semiconductor chip has a plurality of conductive pads disposed on its top surface and the conductive pads face the at least one first insulative material; covering a package unit on the at least two semiconductor chips; and overturning the package unit and removing the adhesive polymeric material in order to make the at least one first insulative material exposed faceup.

The method further includes: removing one part of the at least one first insulative material to form at least one first insulative layer among the conductive pads in order to insulate the conductive pads from each other; forming a plurality of first conductive layers on the at least one first insulative layer for respectively and electrically connecting to the conductive pads; forming a plurality of second insulative layers among the first conductive layers in order to insulate the first conductive layers from each other; respectively forming a plurality of second conductive layers on the first conductive layers for electrically connecting to the conductive pads; and forming at least two semiconductor chip package structures by a cutting process.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a side, schematic view of an LED package structure via a wire-bonding process according to the prior art;

FIG. 2 is a flowchart of a method of making semiconductor chip package structures for achieving electrical connection without using a wire-bonding process according to the first and the second embodiment of the present invention;

FIGS. 2A to 2K are cross-sectional, schematic views of two semiconductor chip package structures for achieving electrical connection without using a wire-bonding process according to the first embodiment of the present invention, at different stages of the packaging processes, respectively; and

FIGS. 3A to 3D are partial, cross-sectional, schematic views of two semiconductor chip package structures for achieving electrical connection without using a wire-bonding process according to the second embodiment of the present invention, at different stages of the packaging processes, respectively.

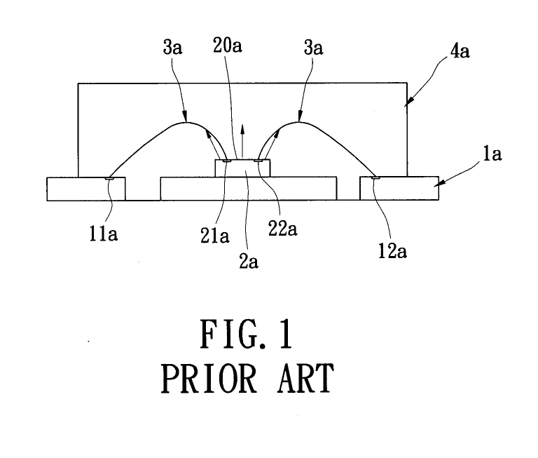

### DETAILED DESCRIPTION OF PREFERRED EMBODIMENTS

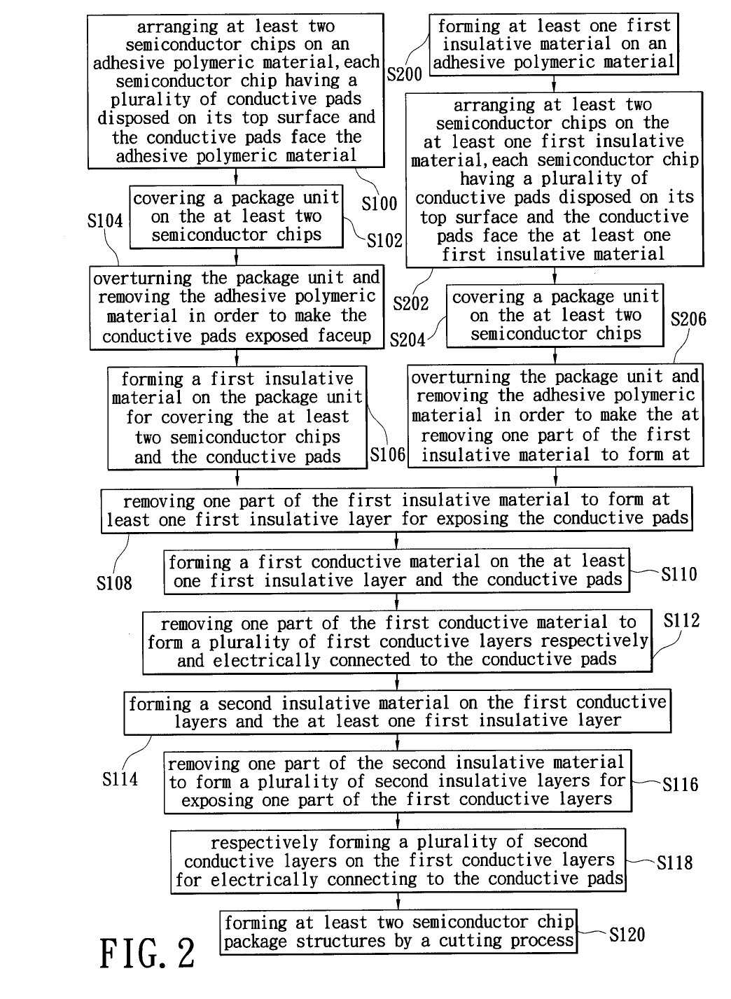

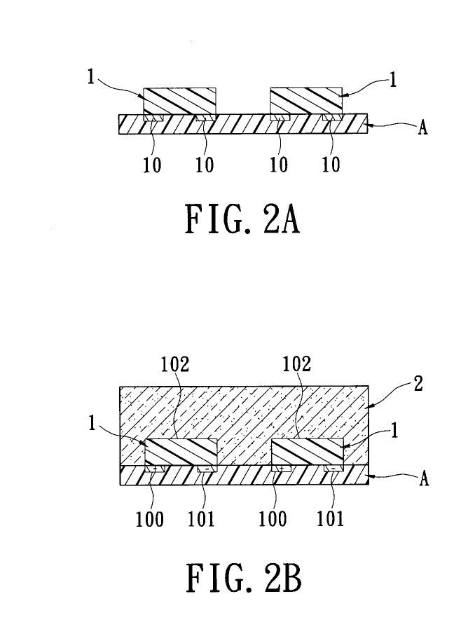

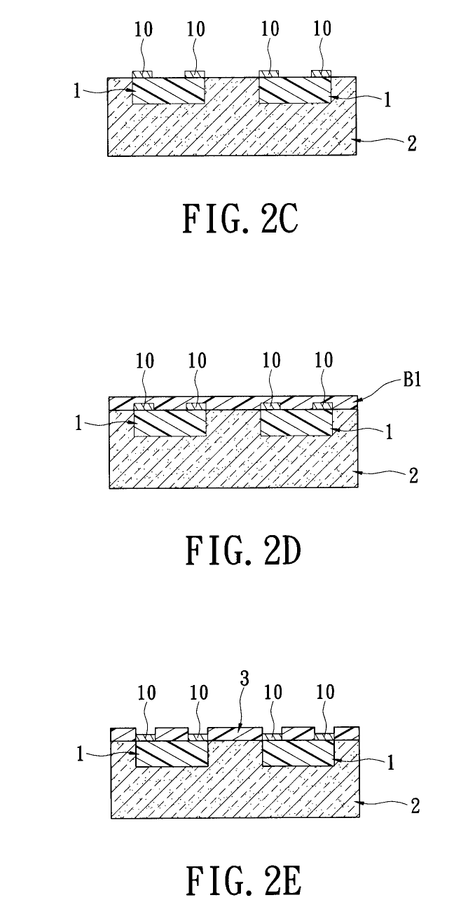

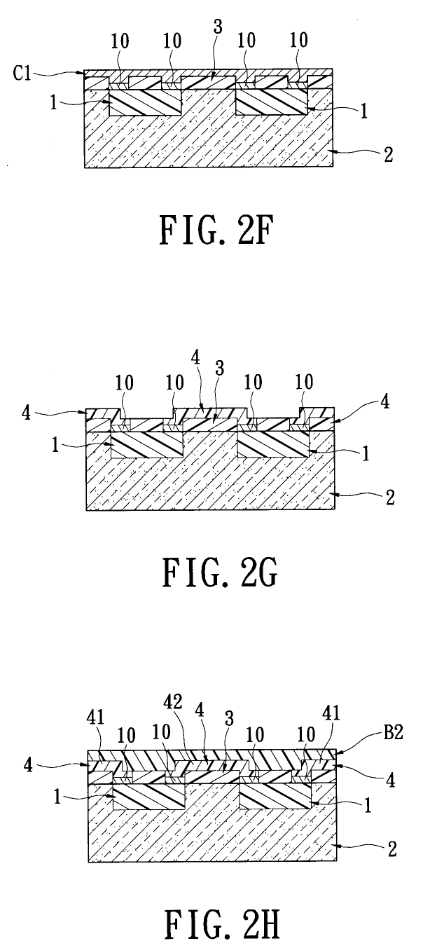

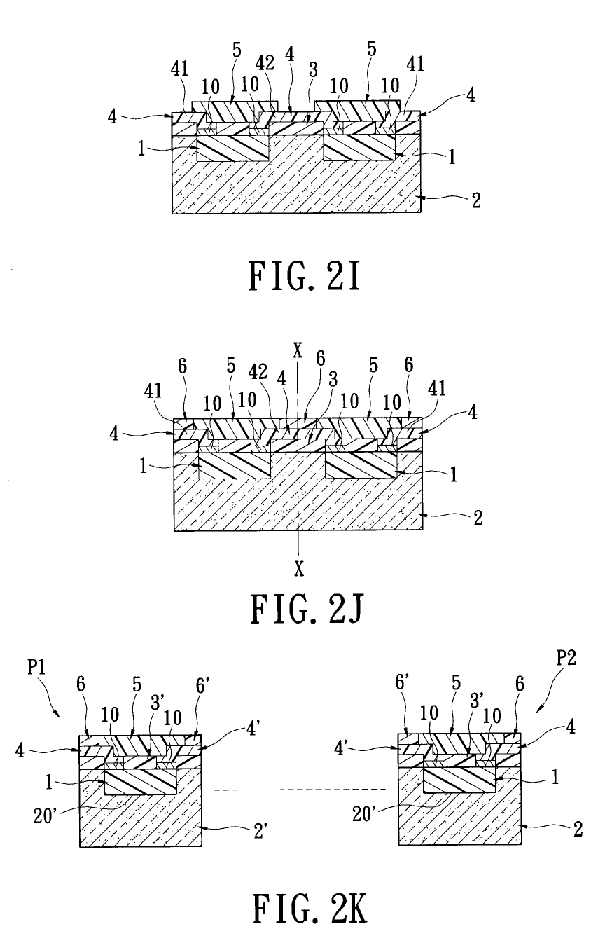

Referring to FIGS. 2 and 2A-2K, the first embodiment of the present invention provides a method of making semiconductor chip package structures for achieving electrical connection without using a wire-bonding process, including as follows:

Step S100 is: referring to FIGS. 2 and 2A, arranging at least two semiconductor chips 1 on an adhesive polymeric material A, and each semiconductor chip 1 having a plurality of conductive pads 10 disposed on its top surface and the conductive pads 10 face the adhesive polymeric material A. In the first embodiment, each semiconductor chip 1 can be an LED (light emitted diode) chip set.

Step S102 is: referring to FIGS. 2 and 2B, covering a package unit 2 on the at least two semiconductor chips 1. In the first embodiment, the package unit 2 can be a fluorescent material, and the conductive pads 10 of each semiconductor chip 1 are divided into a positive electrode pad 100 and a negative electrode pad 101. In addition, each semiconductor chips 1 has light-emitting surface 102 on its bottom surface and opposite the conductive pads 10.

Step S104 is: referring to FIGS. 2 and 2C, overturning the package unit 2 and removing the adhesive polymeric material A in order to make the conductive pads 10 exposed faceup.

Step S106 is: referring to FIGS. 2 and 2D, forming a first insulative material B1 on the package unit 2 for covering the at least two semiconductor chips 1 and the conductive pads 10. In addition, the first insulative material B1 is formed on the package unit 2 by printing, coasting or spraying, and the first insulative material B1 is hardened by pre-curing.

Step S108 is: referring to FIGS. 2 and 2E, removing one part of the first insulative material B1 to form at least one first insulative layer 3 for exposing the conductive pads 10. In other words, the one part of the first insulative material B1 is removed by matching an exposure process, a development process and an etching process to form the at least one first insulative layer 3 among the conductive pads 10 in order to insulate the conductive pads 10 from each other.

Step S110 is: referring to FIGS. 2 and 2F, forming a first conductive material C1 on the at least one first insulative layer 3 and the conductive pads 10. In addition, the first conductive material C1 is formed on the at least one first insulative layer 3 and the conductive pads 10 by evaporating, sputtering, electroplating or electroless plating.

Step S112 is: referring to FIGS. 2 and 2G, removing one part of the first conductive material C1 to form a plurality of first conductive layers 4 respectively and electrically connected to the conductive pads 10. In other words, the one part of the first conductive material C1 is removed by matching an exposure process, a development process and an etching process to form the first conductive layers 4 on the at least one first insulative layer 3 for respectively and electrically connecting to the conductive pads 10.

Step S114 is: referring to FIGS. 2 and 2H, forming a second insulative material B2 on the first conductive layers 4 and the at least one first insulative layer 3. In additional, the second insulative material B2 is formed on the first conductive layers 4 and the at least one first insulative layer 3 by printing, coasting or spraying, and the second insulative material B2 is hardened by pre-curing. Furthermore, the first conductive layers 4 are divided into a plurality of first part conductive layers 41 and a plurality of second part conductive layers 42. One side of each first part conductive layer 41 is electrically connected to the corresponding conductive pad 10, and two opposite sides of each second part conducive layer 42 are electrically connected to the two corresponding conductive pads 10.

Step S116 is: referring to FIGS. 2 and 2I, removing one part of the second insulative material B2 to form a plurality of second insulative layers 5 for exposing one part of the first conductive layers 4. In other words, the one part of the second insulative material B2 is removed by matching an exposure process, a development process and an etching process to form the second insulative layers 5 among the first conductive layers 4 in order to insulate the first conductive layers 4 from each other. Furthermore, each second insulative layer 5 is between each first part conductive layer 41 and each second part conductive layer 42.

Step S118 is: referring to FIGS. 2 and 2J, respectively forming a plurality of second conductive layers 6 on the first conductive layers 4 for electrically connecting to the conductive pads 10. In addition, the second conductive layers 6 are respectively formed on the first conductive layers 4 by evaporating, sputtering, electroplating or electroless plating. Furthermore, one part of the second conductive layers 6 (the outer second conductive layers 6) is electrically connected to the opposite side of each first part conductive layer 41, and the other part of the second conductive layers 6 (the center second conductive layers 6) is electrically disposed on a center position of each second part conductive layer 42.

Step S120 is: referring to FIGS. 2 and 2K, forming at least two semiconductor chip package structures (P1, P2) by a cutting process along the dotted line X in FIG. 2J.

Therefore, each semiconductor chip package structure (P1, P2) has a semiconductor chip 1, a package unit 2′, a first insulative unit, a first conductive unit, a second insulative unit, and a second conductive unit.

The package unit 2′ has at least one receiving groove 20′. The semiconductor chip 1 is received in the at least one receiving groove 20′ and has a plurality of conductive pads 10 disposed on its top surface. The first insulative unit has at least one first insulative layer 3′ formed among the conductive pads 10 in order to insulate the conductive pads 10 from each other. The first conductive unit has a plurality of first conductive layers (4, 4′) formed on the at least one first insulative layer 3′, and one side of each first conductive layer (4, 4′) is electrically connected to the corresponding conductive pad 10. The second insulative unit has at least one second insulative layer 5 formed among the first conductive layers (4, 4′) in order to insulate the first conductive layers (4, 4′) from each other. The second conductive unit has a plurality of second conductive layers (6, 6′) respectively formed on the other opposite sides of the first conductive layers (4, 4′).

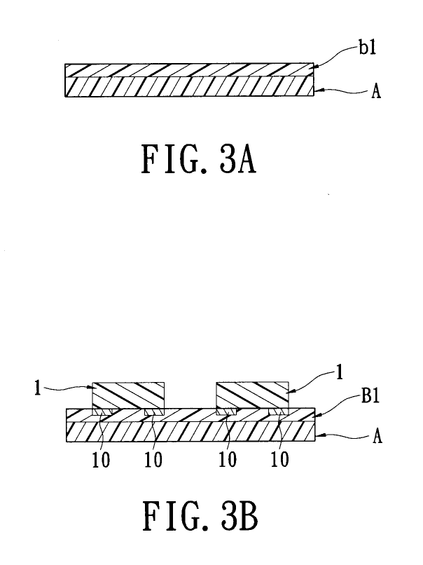

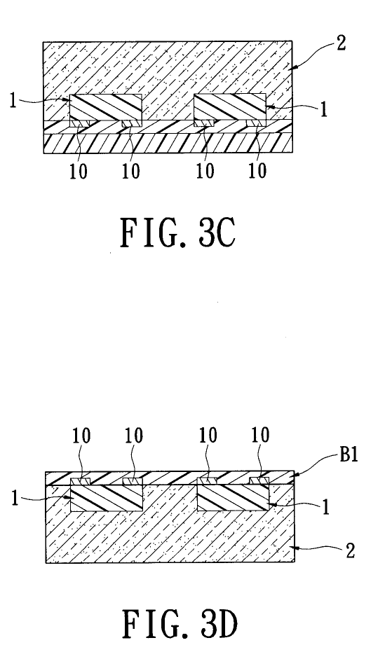

Referring to FIGS. 2 and 3A-3D, the second embodiment of the present invention provides a method of making semiconductor chip package structures for achieving electrical connection without using a wire-bonding process, including as follows:

Step S200 is: referring to FIGS. 2 and 3A, forming at least one first insulative material b1 (the first insulative material b1 has not been pressed yet) on an adhesive polymeric material A.

Step S202 is: referring to FIGS. 2 and 3B, arranging at least two semiconductor chips 1 on the at least one first insulative material B1 (the first insulative material B1 has been pressed), and each semiconductor chip 1 having a plurality of conductive pads 10 disposed on its top surface and the conductive pads 10 face the at least one first insulative material B1.

Step S204 is: referring to FIGS. 2 and 3C, covering a package unit 2 on the at least two semiconductor chips 1.

Step S206 is: referring to FIGS. 2 and 3D, overturning the package unit 2 and removing the adhesive polymeric material A in order to make the at least one first insulative material B1 exposed faceup;

The following steps of the second embodiment are same as step S108 to step S120 of the first embodiment for making at least two semiconductor chip package structures (P1, P2).

Furthermore, there are some different choices of the semiconductor chips 1 and the package unit 2 in the first and the second embodiment, as follows:

1. Each semiconductor chip 1 can be an (light-emitting diode) chip set, and the package unit 2 can be a fluorescent material. The conductive pads 10 of each semiconductor chip 1 are divided into a positive electrode pad 100 and a negative electrode pad 101. For example, the LED chip set has a blue LED chip. Therefore, the match of the blue LED chip and the fluorescent material can generate white light.

2. Each semiconductor chip 1 can be an (light-emitting diode) chip set, and the package unit 2 can be a transparent material. The conductive pads 10 of each semiconductor chip 1 are divided into a positive electrode pad 100 and a negative electrode pad 101. For example, the LED chip set is an LED chip set for generating white light (such as the LED chip set is composed of a red LED chip, a green LED chip and a blue LED chip). Therefore, the match of the LED chip set for generating white light and the transparent material can generate white light.

3. Each semiconductor chip 1 can be a light-sensing chip, and the package unit 2 can be a transparent material or a translucent material. The conductive pads 10 of each semiconductor chip 1 at least are divided into an electrode pad set and a signal pad set.

4. Each semiconductor chip 1 can be an IC (Integrated Circuit) chip, and the package unit 2 can be an opaque material. The conductive pads 10 of each semiconductor chip 1 at least are divided into an electrode pad set and a signal pad set.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A semiconductor chip package structure for achieving electrical connection without using a wire-bonding process, comprising:
a package unit having at least one receiving groove;
at least one semiconductor chip received in the at least one receiving groove and having a plurality of conductive pads disposed on its top surface;
a first insulative unit having at least one first insulative layer formed among the conductive pads in order to insulate the conductive pads from each other;
a first conductive unit having a plurality of first conductive layers formed on the at least one first insulative layer, and one side of each first conductive layer electrically connected to the corresponding conductive pad;
a second insulative unit having at least one second insulative layer formed among the first conductive layers in order to insulate the first conductive layers from each other; and
a second conductive unit having a plurality of second conductive layers respectively formed on the other opposite sides of the first conductive layers.

2. The semiconductor chip package structure as claimed in claim 1, wherein the at least one semiconductor chip is an LED chip set, the package unit is a fluorescent material or a transparent material, the conductive pads are divided into a positive electrode pad and a negative electrode pad, and the semiconductor chip has light-emitting surface on its bottom surface and opposite the conductive pads.

3. The semiconductor chip package structure as claimed in claim 1, wherein the at least one semiconductor chip is a light-sensing chip, the package unit is a transparent material or a translucent material, and the conductive pads are divided into an electrode pad set and a signal pad set.

4. The semiconductor chip package structure as claimed in claim 1, wherein the at least one semiconductor chip is an IC (Integrated Circuit) chip, the package unit is an opaque material, and the conductive pads are divided into an electrode pad set and a signal pad set.

5. The semiconductor chip package structure as claimed in claim 1, wherein the at least one first insulative layer is formed on the package unit and the at least one semiconductor chip.

6. The semiconductor chip package structure as claimed in claim 1, wherein the at least one second insulative layer is formed on the first conductive layers.

7. A method of making semiconductor chip package structures for achieving electrical connection without using a wire-bonding process, comprising:
arranging at least two semiconductor chips on an adhesive polymeric material, wherein each semiconductor chip has a plurality of conductive pads disposed on its top surface and the conductive pads face the adhesive polymeric material;
covering a package unit on the at least two semiconductor chips;
overturning the package unit and removing the adhesive polymeric material in order to make the conductive pads exposed faceup;
forming at least one first insulative layer among the conductive pads in order to insulate the conductive pads from each other;
forming a plurality of first conductive layers on the at least one first insulative layer for respectively and electrically connecting to the conductive pads;
forming a plurality of second insulative layers among the first conductive layers in order to insulate the first conductive layers from each other;
respectively forming a plurality of second conductive layers on the first conductive layers for electrically connecting to the conductive pads; and
forming at least two semiconductor chip package structures by a cutting process.

8. The method as claimed in claim 7, wherein each semiconductor chip is an LED chip set, the package unit is a fluorescent material or a transparent material, the conductive pads of each semiconductor chip are divided into a positive electrode pad and a negative electrode pad, and the semiconductor chip has light-emitting surface on its bottom surface and opposite the conductive pads.

9. The method as claimed in claim 7, wherein each semiconductor chip is a light-sensing chip, the package unit is a transparent material or a translucent material, and the conductive pads of each semiconductor chip are divided into an electrode pad set and a signal pad set.

10. The method as claimed in claim 7, wherein each semiconductor chip is an IC (Integrated Circuit) chip, the package unit is an opaque material, and the conductive pads of each semiconductor chip are divided into an electrode pad set and a signal pad set.

11. The method as claimed in claim 7, wherein the step of forming at least one first insulative layer further comprises:
forming a first insulative material on the package unit for covering the at least two semiconductor chips and the conductive pads; and
removing one part of the first insulative material to form the at least one first insulative layer for exposing the conductive pads;
wherein the first insulative material is formed on the package unit by printing, coasting or spraying, and the first insulative material is hardened by pre-curing and the one part of the first insulative material is removed by matching an exposure process, a development process and an etching process.

12. The method as claimed in claim 7, wherein the step of forming the first conductive layers further comprises:
forming a first conductive material on the at least one first insulative layer and the conductive pads; and
removing one part of the first conductive material to form the first conductive layers respectively and electrically connected to the conductive pads;
wherein the first conductive material is formed on the at least one first insulative layer and the conductive pads by evaporating, sputtering, electroplating or electroless plating, and the one part of the first conductive material is removed by matching an exposure process, a development process and an etching process.

13. The method as claimed in claim 7, wherein the step of forming the second insulative layers further comprises:
forming a second insulative material on the first conductive layers and the at least one first insulative layer; and
removing one part of the second insulative material to form the second insulative layers for exposing one part of the first conductive layers;
wherein the second insulative material is formed on the first conductive layers and the at least one first insulative layer by printing, coasting or spraying, and the second insulative material is hardened by pre-curing and the one part of the second insulative material is removed by matching an exposure process, a development process and an etching process.

14. The method as claimed in claim 7, wherein the second conductive layers are respectively formed on the first conductive layers by evaporating, sputtering, electroplating or electroless plating.

15. The method as claimed in claim 7, wherein the first conductive layers are divided into a plurality of first part conductive layers and a plurality of second part conductive layers, one side of each first part conductive layer is electrically connected to the corresponding conductive pad, two opposite sides of each second part conducive layer are electrically connected to the two corresponding conductive pads, each second insulative layer is formed between each first part conductive layer and each second part conductive layer, one part of the second conductive layers is electrically connected to the opposite side of each first part conductive layer, and the other part of the second conductive layers is electrically disposed on a center position of each second part conductive layer.

16. A method of making semiconductor chip package structures for achieving electrical connection without using a wire-bonding process, comprising:
forming at least one first insulative material on an adhesive polymeric material;
arranging at least two semiconductor chips on the at least one first insulative material, wherein each semiconductor chip has a plurality of conductive pads disposed on its top surface and the conductive pads face the at least one first insulative material;
covering a package unit on the at least two semiconductor chips;
overturning the package unit and removing the adhesive polymeric material in order to make the at least one first insulative material exposed faceup;
removing one part of the at least one first insulative material to form at least one first insulative layer among the conductive pads in order to insulate the conductive pads from each other;
forming a plurality of first conductive layers on the at least one first insulative layer for respectively and electrically connecting to the conductive pads;
forming a plurality of second insulative layers among the first conductive layers in order to insulate the first conductive layers from each other;
respectively forming a plurality of second conductive layers on the first conductive layers for electrically connecting to the conductive pads; and
forming at least two semiconductor chip package structures by a cutting process.

17. The method as claimed in claim 16, wherein each semiconductor chip is an LED chip set, the package unit is a fluorescent material or a transparent material, the conductive pads of each semiconductor chip are divided into a positive electrode pad and a negative electrode pad, and the semiconductor chip has light-emitting surface on its bottom surface and opposite the conductive pads.

18. The method as claimed in claim 16, wherein each semiconductor chip is a light-sensing chip, the package unit is a transparent material or a translucent material, and the conductive pads of each semiconductor chip are divided into an electrode pad set and a signal pad set.

19. The method as claimed in claim 16, wherein each semiconductor chip is an IC (Integrated Circuit) chip, the package unit is an opaque material, and the conductive pads of each semiconductor chip are divided into an electrode pad set and a signal pad set.

20. The method as claimed in claim 16, wherein the at least one first insulative material is formed on the package unit for covering the at least two semiconductor chips and the conductive pads by printing, coasting or spraying, and the at least one first insulative material is hardened by pre-curing and the one part of the at least one first insulative material is removed for exposing the conductive pads by matching an exposure process, a development process and an etching process.

21. The method as claimed in claim 16, wherein the step of forming the first conductive layers further comprises:
forming a first conductive material on the at least one first insulative layer and the conductive pads; and
removing one part of the first conductive material to form the first conductive layers respectively and electrically connected to the conductive pads;
wherein the first conductive material is formed on the at least one first insulative layer and the conductive pads by evaporating, sputtering, electroplating or electroless plating, and the one part of the first conductive material is removed by matching an exposure process, a development process and an etching process.

22. The method as claimed in claim 16, wherein the step of forming the second insulative layers further comprises:
forming a second insulative material on the first conductive layers and the at least one first insulative layer; and
removing one part of the second insulative material to form the second insulative layers for exposing one part of the first conductive layers;
wherein the second insulative material is formed on the first conductive layers and the at least one first insulative layer by printing, coasting or spraying, and the second insulative material is hardened by pre-curing and the one part of the second insulative material is removed by matching an exposure process, a development process and an etching process.

23. The method as claimed in claim 16, wherein the second conductive layers are respectively formed on the first conductive layers by evaporating, sputtering, electroplating or electroless plating.

24. The method as claimed in claim 16, wherein the first conductive layers are divided into a plurality of first part conductive layers and a plurality of second part conductive layers, one side of each first part conductive layer is electrically connected to the corresponding conductive pad, two opposite sides of each second part conducive layer are electrically connected to the two corresponding conductive pads, each second insulative layer is formed between each first part conductive layer and each second part conductive layer, one part of the second conductive layers is electrically connected to the opposite side of each first part conductive layer, and the other part of the second conductive layers is electrically disposed on a center position of each second part conductive layer.
